(19) United States
(12) Patent Application Publication
(10) Pub. No.: US 2009/0164859 A1
(43) Pub. Date: Jun. 25, 2009

(54) DRIVING CIRCUIT OF DISPLAY APPARATUS AND DRIVING METHOD THEREOF

(76) Inventors: Ming-Huang Liu, Taipei Hsien (TW); Wen-Chi Wu, Tao-Yuan City (TW); Meng-Yong Lin, Hsinchu City (TW); Bo-Chang Wu, Taichung County (TW); Chi-Mo Huang, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 12/042,323

(22) Filed: Mar. 4, 2008

(30) Foreign Application Priority Data
Dec. 21, 2007 (TW) 096149211

(51) Int. Cl. G01R 31/28

(52) U.S. Cl. 714/727

(57) ABSTRACT

A driving circuit of a display apparatus includes a decoder coupled to a plurality of scan lines of a display panel for decoding a plurality of input signals to output a plurality of scan line driving signals to thereby enable at least one scan line of the plurality of scan lines, and a plurality of control units (respectively coupled to the plurality of scan lines) for receiving an output enable signal to disable the plurality of scan lines during an interval between two scan lines being enabled.

### BACKGROUND OF THE INVENTION

1. Field of the Invention

The present invention relates to a driving circuit of a display apparatus, and more particularly, to a scan driving circuit of a liquid crystal display (LCD) and driving method thereof.

2. Description of the Prior Art

Please refer to FIG. 1. FIG. 1 is a diagram illustrating a prior art scan driving circuit 100. As shown in FIG. 1, the scan driving circuit 100 comprises a decoder 110, a plurality of level shifters 120, and a plurality of buffer amplifiers 130. The operating principles of the prior art scan driving circuit 100 are described as follows: first, the decoder 110 receives a plurality of input signals X₁, X₂, . . . , Xₙ to generate a plurality of scan line driving signals S₁, S₂, . . . , Sₘ, and then the scan line driving signals S₁, S₂, . . . , Sₘ are processed by the level shifters 120 and the buffer amplifiers 130 to become a plurality of level shifted scan line driving signals to thereby enable a target scan line (e.g., G₁) and disable other scan lines (e.g., G₂, . . . , Gₘ). The voltage level of the level shifted scan line driving signal for enabling the target scan line is transformed from a low voltage (about 1.8V) to a high voltage (about 16V) by the level shifter 120. The voltage level of the level shifted scan line driving signals for disabling other scan lines are transformed from a low voltage (about 0V) to a high voltage (about −16V) by the level shifters 120.

However, in the scan driving circuit 100, a number of level shifters 120 is equal to a number of scan lines of display apparatus. That is, if there are 128 scan lines in the display apparatus, the scan driving circuit 100 comprises at least 128 level shifters 120. In addition, because the level shifter 120 requires a larger circuit layout area, the scan driving circuit 100 therefore needs a larger circuit layout area and further results in higher manufacturing costs.

### SUMMARY OF THE INVENTION

It is therefore one of an objectives of the present invention to provide a scan driving circuit having fewer level shifters and driving method thereof, to solve the above-mentioned problems.

According to one embodiment of the present invention, a driving circuit of a display apparatus comprises: a decoder, coupled to a plurality of scan lines of a display panel, for decoding a plurality of input signals to output a plurality of scan line driving signals to thereby enable at least one scan line of the plurality of scan lines; and a plurality of control units, respectively coupled to the plurality of scan lines, for receiving an output enable signal to disable the plurality of scan lines during an interval between two scan lines enabled.

According to another embodiment of the present invention, a driving method of a display apparatus comprises: decoding a plurality of input signals to output a plurality of scan line driving signals to thereby enable at least one scan line of the plurality of scan lines; receiving an output enable signal to disable the plurality of scan lines during an interval between two scan lines enabled.

According to the driving circuit of the display apparatus and the driving method disclosed by the present invention, the required level shifters of the driving circuit are significantly reduced. Therefore, the circuit layout area of the driving circuit is reduced and further lowers manufacturing costs.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a prior art scan driving circuit.

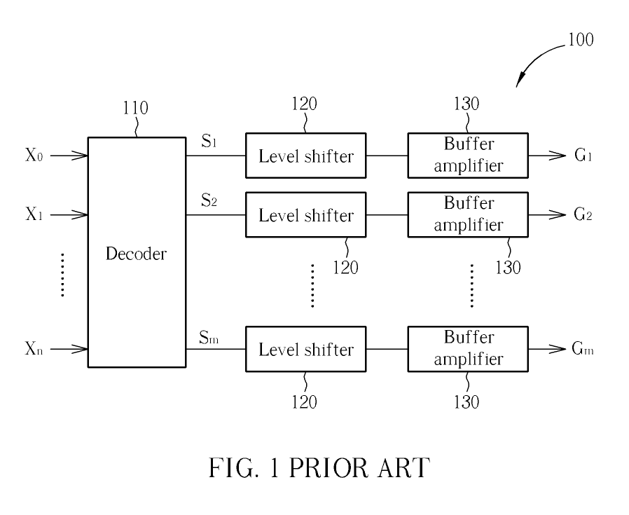

FIG. 2 is a diagram illustrating a driving circuit of a display apparatus according to one embodiment of the present invention.

FIG. 3 is a circuit diagram illustrating a first embodiment of the control unit shown in FIG. 2.

FIG. 4 is a timing diagram of control signals of the driving circuit shown in FIG. 2.

FIG. 5 is a circuit diagram illustrating a second embodiment of the control unit shown in FIG. 2.

FIG. 6 is a circuit diagram illustrating a third embodiment of the control unit shown in FIG. 2.

FIG. 7 is a circuit diagram illustrating a fourth embodiment of the control unit shown in FIG. 2.

FIG. 8 is a diagram illustrating a 1-to-4 decoder applied to the driving circuit of the present invention.

### DETAILED DESCRIPTION

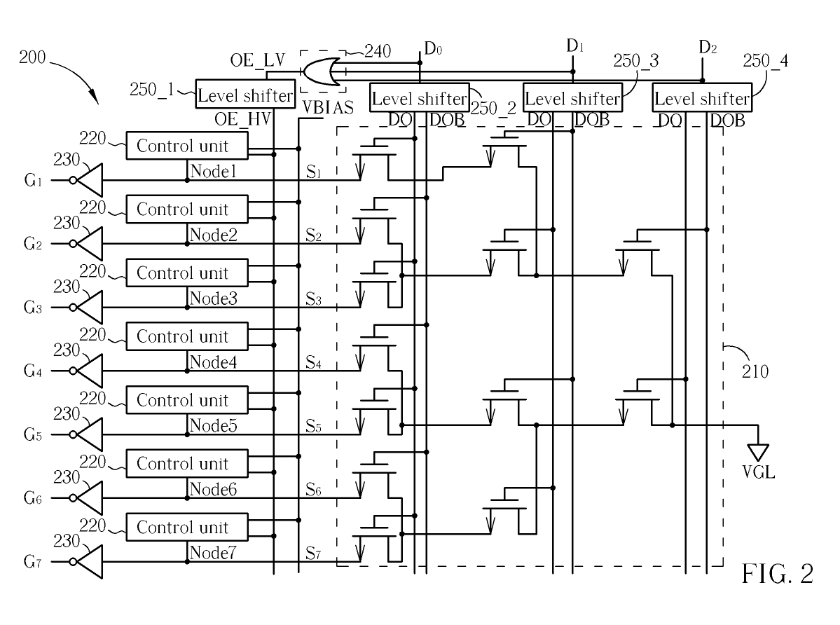

Please refer to FIG. 2. FIG. 2 is a diagram illustrating a driving circuit 200 of a display apparatus according to one embodiment of the present invention. As shown in FIG. 2, the driving circuit 200 comprises a decoder 210, a plurality of control units 220, a plurality of inverters 230, a output enable (OE) signal generating circuit 240, and a plurality of level shifters 250_1, 250_2, 250_3, 250_4. In addition, in this embodiment, the OE signal generating circuit 240 is an OR gate. Please note that, without departing from the present invention, FIG. 2 only shows the elements related to the present invention. In addition, the circuit structure shown in FIG. 2 is merely an example and is not meant to be a limitation of the present invention.

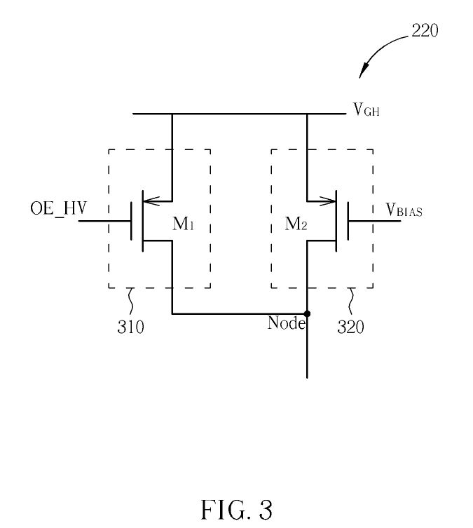

Please refer to FIG. 3. FIG. 3 is a circuit diagram illustrating a first embodiment of the control unit shown in FIG. 2. As shown in FIG. 3, the control unit 220 comprises a control circuit 310 and a voltage stabilizing circuit 320, where the control circuit 310 and the voltage stabilizing circuit 320 are implemented by P-type metal-oxide semiconductors (PMOS) M1 and M2, respectively. The gate electrode of the PMOS M1 is connected to an output node of the OE signal generating circuit 240, and the gate electrode of the PMOS M2 is connected to a bias voltage V_{BIAS}. In this embodiment, the bias voltage V_{BIAS} is utilized to enable the PMOS M2 with a tiny current (about 0.1 uA). Additionally, the source electrodes of the control circuit 310 and the voltage stabilizing circuit 320 are connected to a voltage V_{GH}.

To conveniently describe the present invention, the driving circuit 200 of the display apparatus only corresponds to seven scan lines G₁-G₇. However, after studying the following skills of the driving circuit 200, a person skilled in this art can easily apply this to a driving circuit used to drive a different number of scan lines. The operating methods of the driving circuit 200 are described as follows.

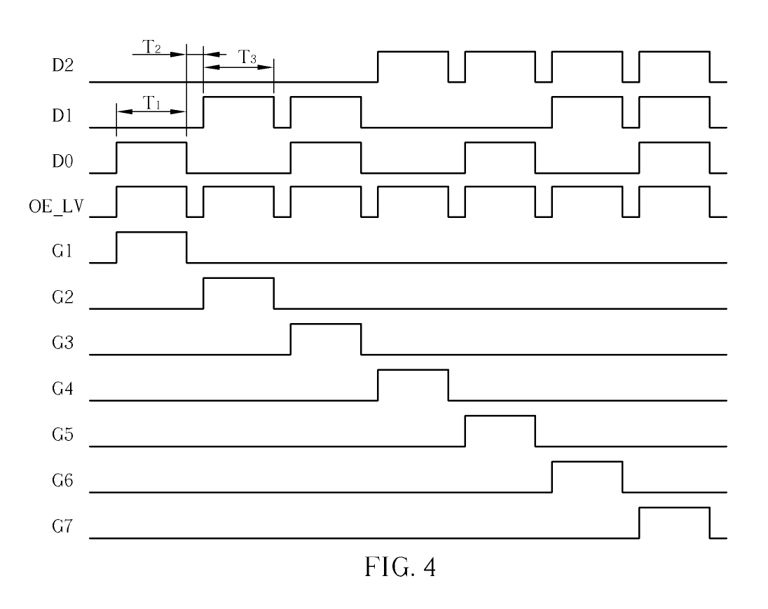

The driving circuit 200 is used to sequentially enable a plurality of scan lines to make the scan lines G₁-G₇ have a timing diagram of control signals shown in FIG. 4. Please refer to FIG. 2, FIG. 3, and FIG. 4 at the same time. FIG. 4 is a timing diagram of control signals of the driving circuit 200 shown in FIG. 2. In the driving circuit 200, first, voltage levels of a plurality of digital input signals D₀, D₁, D₂ are adjusted by the level shifter 250_2, 250_3, 250_4; in this embodiment, 1.8V is adjusted to be 16V, and 0V is adjusted to be 0V. Each level shifter outputs two level shifted signals DO, DOB to the decoder 210, where the level shifted signals DO, DOB have opposite phases. In this embodiment, if the digital input signal is at a high voltage level (1.8V), the level shifted signal DO is at high voltage level (16V) while the level shifted signal DOB is at a low voltage level (−16V). Similarly, if the digital input signal is at a low voltage level (0V), the level shifted signal DO is at the low voltage level (−16V) while the level shifted signal DOB is at the high voltage level (16V). Next, the decoder 210 decodes the digital input signals D₀, D₁, D₂ to output a plurality of scan line driving signals S₁-S₇ to enable at least one scan line of the scan lines G₁-G₇. For example, at the time T₁ shown in FIG. 4, the digital input signals D₀, D₁, D₂ are (1, 0, 0), then the scan line driving signal S₁ is at a low voltage level and the scan line driving signals S₂-S₇ are at high voltage levels. After the scan line driving signals S₁-S₇ are inverted by the inverters 230, the scan line G₁ is at a high voltage level (enabled) and the scan lines G₂-G₇ are at low voltage levels (disabled). In addition, because the digital input signals D₀, D₁, D₂ are (1, 0, 0), the OE signal OE_LV outputted from OE signal generating circuit 240 and the level shifted OE signal OE_HV outputted from the level shifter 250_1 are at high voltage levels (e.g., 1.8V and 16V). Therefore, the PMOS M1 of the control unit 220 shown in FIG. 3 is disabled, and voltages of nodes Node1-Node7 will not be influenced.

Next, at time T₂ shown in FIG. 4, the digital input signals D₀, D₁, D₂ are (0, 0, 0). Therefore, not all the transistors on the path between the voltage VGL and each node are enabled, and the voltage levels of the scan line driving signals S₁-S₇ are the same as the voltage levels at time T₁ (i.e., the scan line driving signal S₁ is at a low voltage level, and the scan line driving signals S₂-S₇ are at high voltage level). At this time, because the digital input signals D₀, D₁, D₂ are (0, 0, 0), the OE signal OE_LV outputted from the OE signal generating circuit 240 and the level shifted OE signal OE_HV outputted from the level shifter 250_1 are at low voltage levels (e.g., 0V and −16V). Therefore, the PMOS M1 of the control unit 220 shown in FIG. 3 is enabled, and the voltage level of the node Node1 originally having the low voltage level is pulled high to the voltage V_{GH} (16V in this embodiment), and nodes Node2-Node7 retain their original voltage levels (16V). Therefore, the scan lines G₁-G₇ are all at low voltage levels (disabled).

Similarly, at the time T3 shown in FIG. 4, the digital input signals D₀, D₁, D₂ are (0, 1, 0), and therefore the scan line driving signal S₂ is at a low voltage level and the scan line driving signals S₁, S₃-S₇ are at high voltage levels. After the scan line driving signals S₁-S₇ are inverted by the inverters 230, the scan line G₂ is at high voltage level (enabled) and the scan lines G₁, G₃-G₇ are at low voltage levels (disabled). In addition, because the digital input signals D₀, D₁, D₂ are (0, 1, 0), the OE signal OE_LV outputted from the OE signal generating circuit 240 and the level shifted OE signal OE_HV outputted from the level shifter 250_1 are at high voltage levels (e.g., 1.8V and 16V). Therefore, the PMOS M1 of the control unit 220 shown in FIG. 3 is disabled, and the voltage levels of the nodes Node1-Node7 will not be influenced. In the following operations, different combinations of the digital input signals D₀, D₁, D₂ are used to sequentially enable the scan lines G₃-G₇, and the digital input signals (0, 0, 0) are inputted during an interval between two scan lines enabled to disable the scan lines. As the operations of the driving circuit 200 are similar to operations at time T₁-T₃, a person skilled in this art should be able to apply the above teachings of the present invention to the following operations of the driving circuit 200. Further description is therefore omitted here.

In addition, at the same time, only one scan line is enabled, therefore, the time each scan line is disabled is close to a frame time. That is, in the driving circuit 200, the nodes Node1-Node7 are at high voltage levels (16V) most of the time. However, because the voltage levels of the nodes Node1-Node7 may drop due to leakage current, the voltages of the scan lines G₁-G₇ originally at low voltage levels may increase and may result in the transistors of corresponding pixels being not completely turned off, further influencing the gray values of those pixels. Therefore, the voltage stabilizing circuit 320 (i.e., PMOS M2) of the control unit 220 shown in FIG. 3 is used to solve this problem. Because the PMOS M2 is turned on with a tiny current (about 0.1 uA) and the source electrode of the PMOS M2 is connected to V_{GH} (16V), the nodes Node1-Node7 can maintain their voltage levels at V_{GH} to prevent the degradation of the display quality due to leakage current. Additionally, because the current of the PMOS M2 is tiny, when a scan line is enabled (where the corresponding scan line driving signal and the node are at low voltage level), the voltage of the corresponding node is almost completely uninfluenced due to the turning on of PMOS M2.

It should be noted that in the driving circuit 200, the OE signal generating circuit 240 is the OR gate and outputs the OE signal according to the digital input signals D₀, D₁, D₂. However, this is merely an embodiment of the present invention. In practice, the OE signal generating circuit 240 can be another circuit and can generate the OE signal according to other signal(s) in the driving circuit 200. In short, as long as the OE signal generating circuit 240 can generate the OE signal OE_LV shown in FIG. 4 according to the signal(s) in the driving circuit 200, these alternative designs are all within the scope of the present invention.

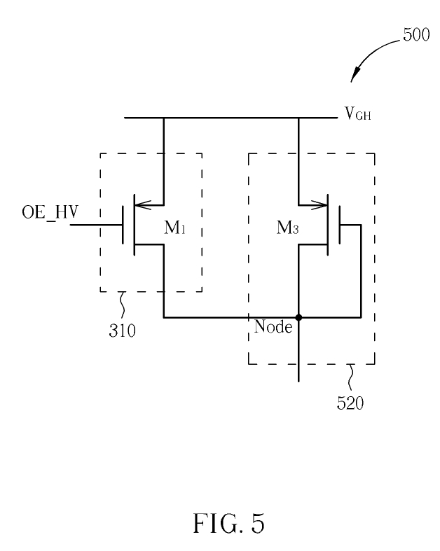

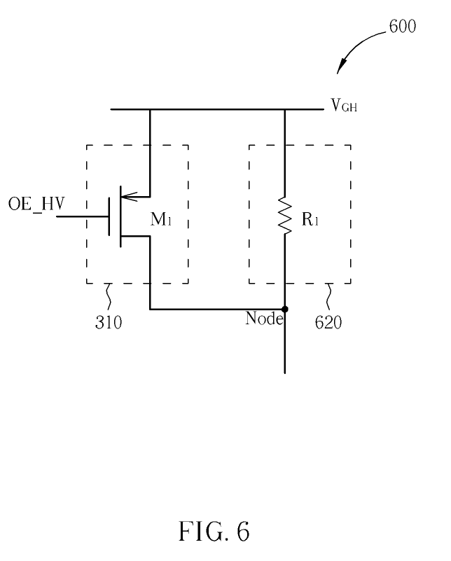

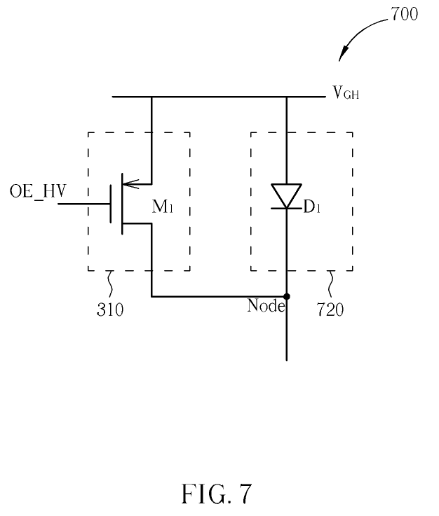

In addition, in the present invention, the voltage stabilizing circuit 320 is a PMOS whose gate electrode is connected the bias voltage V_{BIAS}. However, the voltage stabilizing circuit 320 can also be implemented by other simple methods. FIG. 5-FIG. 7 are circuit diagrams of other embodiments of the control unit shown in FIG. 2. As shown in FIG. 5, a voltage stabilizing circuit 520 of a control unit 500 is a PMOS M3 whose gate electrode and source electrode are connected with each other. In another example, as shown in FIG. 6, a voltage stabilizing circuit 620 of a control unit 600 is a resistor R1; or as shown in FIG. 7, a voltage stabilizing circuit 720 of a control unit 700 is a diode D1. As long as the circuit can maintain the voltages of the nodes Node1-Node7 at a predetermined value, these alternative designs are all within the scope of the present invention.

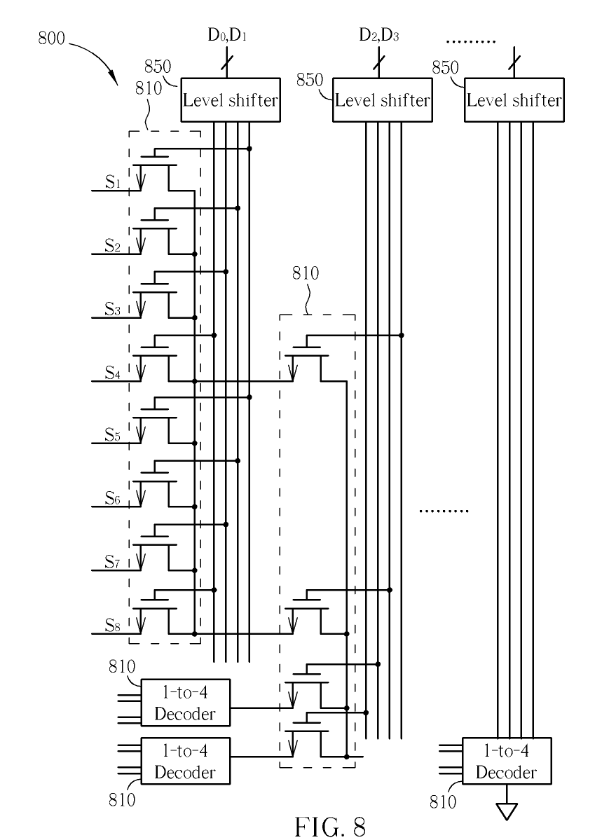

In addition, in the driving circuit 200, the decoder 210 is a binary code. The decoder in the driving circuit 200 can also be a 1-to-4 decoder or another type of decoder, however. FIG. 8 is a diagram illustrating a 1-to-4 decoder 810 applied to the driving circuit of the present invention. Please note that the driving circuit 800 shown in FIG. 8 shows only the differences from the driving circuit 200 shown in FIG. 2, and the operation of the 1-to-4 decoder in the driving circuit 800 is similar to the operation of the decoder 210 in the driving circuit 200. A person skilled in this art can easily understand the operating principles of the driving circuit 800 according to the above teachings of the present invention, and further description therefore is omitted here.

It should be noted that in the driving circuit 200, the decoder 210 outputs a scan line driving signal having a low voltage level, and then this signal is inverted by the inverter 230 to become a signal having a high voltage level to enable the scan line. However, by appropriately modifying the driving circuit 200, the decoder can directly output a can line driving signal having a high voltage level to enable the scan line, and the driving circuit 200 can replace the inverters 230 by buffer amplifiers or even connect the scan lines to the nodes Node1-Node7.

Compared with the prior art scan driving circuit 100, taking seven scan lines as an example, the prior art scan driving circuit 100 needs at least seven level shifters. The driving circuit 200 of the present invention, however, requires only four level shifters. In addition, according the above teachings, the more scan lines there are to be driven, the more the number of level shifters in the driving circuit of the present invention can be reduced. Although the decoder 210 is shown in the driving circuit 200, the decoder 210 can be implemented by a minimum line width process and needs a very small circuit layout area. Therefore, the decoder 200 of the present invention require a smaller circuit layout area and lower manufacturing costs.

Briefly summarizing the driving circuit of the display apparatus and related driving method, in the present invention, a decoder is utilized to decode a plurality of input signals to output a plurality of scan line driving signals to thereby enable at least one scan line. A plurality of control units are utilized to a OE signal to disable all the scan lines during an interval between two scan lines enabled, where each control unit comprises a control circuit for disabling a corresponding scan line during an interval between two scan lines being enabled according to the OE signal. A voltage stabilizing circuit is utilized to maintain a voltage level of a scan line driving signal of a corresponding scan line at a predetermined value when the corresponding scan line is disabled.

Those skilled in the art will readily observe that numerous modifications and alterations of the device and method may be made while retaining the teachings of the invention.

What is claimed is:

1. A driving circuit of a display apparatus, comprising:
a decoder, coupled to a plurality of scan lines of a display panel, for decoding a plurality of input signals to output a plurality of scan line driving signals to thereby enable at least one scan line of the plurality of scan lines; and
a plurality of control units, respectively coupled to the plurality of scan lines, for receiving an output enable signal to disable the plurality of scan lines during an interval between two scan lines being enabled.

2. The driving circuit of the display apparatus of claim 1, further comprising:
an output enable signal generating circuit, coupled to the plurality of control units, for generating the output enable signal according to the plurality of input signals.

3. The driving circuit of the display apparatus of claim 2, further comprising:
a plurality of level shifters, respectively coupled to the decoder and the plurality of control units, for adjusting voltage levels of the plurality of input signals and the output enable signal.

4. The driving circuit of the display apparatus of claim 2, wherein the output enable signal generating circuit is an OR gate.

5. The driving circuit of the display apparatus of claim 1, wherein each control unit of the plurality of control units comprises:
a control unit, for disabling a corresponding scan line during an interval between two scan lines being enabled according to the output enable signal; and
a voltage stabilizing circuit, for maintaining a voltage level of a scan line driving signal of the corresponding scan line at a predetermined value when the corresponding scan line is disabled.

6. The driving circuit of the display apparatus of claim 1, wherein each scan line driving signal is at a first voltage level or a second voltage level, and one of the first and the second voltage levels is a high voltage level, and the other is a low voltage level, the decoder outputs a scan line driving signal having the first voltage level to enable the scan line, and the driving circuit of the display apparatus further comprises:
a plurality of inverters, respectively coupled to the plurality of control units and the plurality of scan lines, for receiving the plurality of scan line driving signals, where an inverter of the plurality of inverters corresponding to the scan line receives the scan line driving signal having the first voltage level to output a target voltage level to enable the scan line.

7. The driving circuit of the display apparatus of claim 6, wherein the target voltage level is the second voltage level.

8. The driving circuit of the display apparatus of claim 6, wherein each control unit of the plurality of control units comprises:
a control unit, for disabling a corresponding scan line during an interval between two scan lines being enabled according to the output enable signal; and
a voltage stabilizing circuit, for maintaining a voltage level of a scan line driving signal of the corresponding scan line at the second voltage level when the corresponding scan line is disabled.

9. The driving circuit of the display apparatus of claim 1, further comprising:
a plurality of level shifters, coupled to the decoder, for adjusting voltage levels of the plurality of input signals.

10. A driving method of a display apparatus, comprising:
decoding a plurality of input signals to output a plurality of scan line driving signals to thereby enable at least one scan line of the plurality of scan lines; and
receiving an output enable signal to disable the plurality of scan lines during an interval between two scan lines being enabled.

11. The driving method of the display apparatus of claim 10, wherein the output enable signal is generated according to the plurality of input signals.

12. The driving method of the display apparatus of claim 11, wherein voltage levels of the plurality of input signals and the output enable signal are adjusted by a level shift operation.

13. The driving method of the display apparatus of claim 11, wherein the output enable signal is generated by an OR operation.

14. The driving method of the display apparatus of claim 10, further comprising:
when a scan line is disabled, performing a voltage stabilizing operation to a voltage level of a scan line driving signal of the scan line and maintaining the voltage level at a predetermined value.

15. The driving method of the display apparatus of claim 10, wherein each scan line driving signal is at a first voltage level or a second voltage level, and one of the first and the second voltage levels is a high voltage level, and the other is a low voltage level, the decoder outputs a scan line driving signal having the first voltage level to enable the scan line, and the driving method further comprises:
inverting the scan line driving signal having the first voltage level to output a target voltage level to enable the scan line.

16. The driving method of the display apparatus of claim 15, wherein the target voltage level is the second voltage level.

17. The driving method of the display apparatus of claim 15, further comprising:
when a scan line is disabled, performing a voltage stabilizing operation to a voltage level of a scan line driving signal of the scan line and maintaining the voltage level at the second voltage level.

18. The driving method of the display apparatus of claim 10, wherein voltage levels of the plurality of input signals are adjusted by a level shift operation.
